(19) United States
(12) Patent Application Publication
(10) Pub. No.: US 2001/0035795 A1
(43) Pub. Date: Nov. 1, 2001

(54) Rubidium atom oscillator

(76) Inventors: Hideyuki Matsuura, Sendai (JP); Ken Atsumi, Sendai (JP); Makiko Sugawara, Sendai (JP); Yoshito Koyama, Kawasaki (JP); Koji Nakamuta, Kawasaki (JP)

Correspondence Address: HELFGOTT & KARAS, P.C., EMPIRE STATE BUILDING, 60TH FLOOR, NEW YORK, NY, 10118, US

(21) Appl. No.: 09/818,353

(22) Filed: Mar. 27, 2001

(30) Foreign Application Priority Data
Apr. 27, 2000 (JP) 2000-126946

(51) Int. Cl. H01S 1/06; H03B 17/00

(52) U.S. Cl. 331/94.1; 331/3

(57) ABSTRACT

A rubidium atom oscillator of a gas cell resonator type includes a cavity resonator having a gas cell in which rubidium gas is enclosed, and a dielectric material member that has thermal conductivity and closely contacts an inner wall of the cavity resonator parallel to an optical axis of an incident light emitted from a pumping source. The gas cell is inserted into the dielectric material member having the thermal conductivity along the optical axis.

### BACKGROUND OF THE INVENTION

1. Field of the Invention

The present invention generally relates to a rubidium atom oscillator of a gas cell resonation type utilizing light pumping, and more particularly to a rubidium atom oscillator equipped with a downsized, highly reliable light-microwave resonator.

Recently, there has been considerable activity in installation of digitized communications networks and broadcasting networks. The digitized networks need a highly precise, highly stable oscillator for a clock source used to generate a clock signal of a transmission apparatus and a reference frequency of a broadcasting station.

Such an oscillator may be a rubidium atom oscillator capable of precisely generating an oscillation frequency in a stabilized state. The recent rubidium atom oscillators have been improved and downsized. However, in practice, further improvement in downsizing of oscillator is required to construct a radio base station in CDMA (Code Division Multiple Access) systems. A downsized oscillator and other functional units that are mounted in a limited space at a high density form such a radio base station. Downsizing of the rubidium atom oscillator may primarily be based on downsizing of a light-microwave resonator.

2. Description of the Related Art

FIG. 1 is a diagram of a conventional rubidium atom oscillator. As shown, the oscillator is made up of a pumping light source 8-1, a cavity resonator (light-microwave resonator) 8-2, a gas cell 8-3, an antenna 8-4, a photodetector 8-5, a frequency control circuit 8-6, a temperature control circuit 8-7, and a frequency adjustment diaphragm (movable plate) 8-8. A pumping light emitted by the pumping source 8-1 is incident to the cavity resonator 8-2 through an aperture of the resonator 8-2. A gas is enclosed in the gas cell 8-3, which is provided in the cavity resonator 8-2. The antenna 8-4 excites a microwave in the cavity resonator 8-2. The photodetector 8-5 detects the amount of light from the pumping source 8-1 that has passed through the gas cell 8-3. The frequency control circuit 8-6 controls the frequency of the microwave for excitation on the basis of the output of the photodetector 8-5. The temperature control circuit 8-8 heats the cavity resonator 8-2 to keep it at a constant temperature. The diaphragm 8-8 has screw holes for adjusting the length of the cavity resonator 8-2 for frequency adjustment.

When the cavity resonator 8-2 is excited at a resonance frequency of the rubidium atom (6.834682 . . . MHz), the rubidium atoms in the gas cell 8-3 absorb the greatest amount of the incident light from the pumping source 8-1. This phenomenon is observed by detecting a decrease of the output of the photodetector 8-5. The frequency control circuit 8-6 controls the frequency of the microwave that excites the cavity resonator 8-2 (emitted via the antenna 8-4) so that the output of the photodetector 8-5 falls in the minimum level.

The above control makes it possible to generate the highly precise oscillation output signal that is synchronized with the resonance frequency of the rubidium atom (6.834682 . . . MHz).

Downsizing of the rubidium atom oscillator depends on how to downsize the cavity resonator (light-microwave resonator) 8-2 in which the microwave of the rubidium atom resonance frequency stands. Conventionally, the rubidium atom oscillator is downsized as follows. The cavity resonator 8-2 is formed by a hollow cylindrical cavity so that its resonance mode is the basic mode of TE111. The thickness and shape of the gas cell 8-3 made of glass placed in the cavity resonator 8-2 are optimized.

However, the above-mentioned attempt to downsize the cavity resonator will reach the limit soon and will encounter difficulty in further downsizing.

### SUMMARY OF THE INVENTION

It is therefore a general object of the present invention to provide a rubidium atom oscillator in which the above disadvantages are eliminated.

A more specific object of the present invention is to provide a rubidium atom oscillator equipped with a simple, downsized light-microwave resonator that has good productivity and precisely generates an oscillation frequency in a stabilized state.

The above objects of the present invention are achieved by a rubidium atom oscillator of a gas cell resonator type comprising: a cavity resonator having a gas cell in which rubidium gas is enclosed; and a dielectric material member that has thermal conductivity and closely contacts an inner wall of the cavity resonator parallel to an optical axis of an incident light emitted from a pumping source. The gas cell is inserted into the dielectric material member having the thermal conductivity along the optical axis. With the above arrangement, heat can efficiently and effectively applied to the gas cell, and power consumption can be reduced. The rubidium atom oscillator thus configured can be used to construct a highly responsibility, stable, reliable, compact light-microwave resonator.

The rubidium atom oscillator may be configured so that the dielectric material member has a hollow cylindrical shape having an outer wall that contacts the inner wall of the cavity resonator; and the gas cell is inserted into an inner wall of the dielectric material member so as to be held by the dielectric material member.

The rubidium atom oscillator may be configured so that the dielectric material member has a hollow cylindrical shape; and the cavity resonator has a hollow cylindrical shape. This rubidium atom oscillator can be used to configure a simple light-microwave resonator.

The rubidium atom oscillator may be configured so that the dielectric material member has at least one cutout portion; and a resonance frequency of the cavity resonator depends on a relative positional relationship between the cutout portion and an electromagnetic field distribution that stands in the cavity resonator. This allows an error that may be introduced during the production process to some extent and enhances productivity.

The rubidium atom oscillator may be configured so that said at least cutout portion is formed in an upper or lower end of the dielectric material member or both.

The rubidium atom oscillator may be configured so that the dielectric material member has at least one hole; and a resonance frequency of the cavity resonator depends on a relative positional relationship between the hole and an electromagnetic field distribution that stands in the cavity resonator.

The rubidium atom oscillator may be configured so that said at least one hole is formed in a side surface of the dielectric material member.

The rubidium atom oscillator may be configured so that the dielectric material member comprises alumina. Thus, the rubidium atom oscillator is less expensive.

A further object of the present invention is to provide a light-microwave resonator comprising: a shield cover; and a rubidium atom oscillator of a gas cell resonator type housed in the shield cover and configured as mentioned above.

### BRIEF DESCRIPTION OF THE DRAWINGS

Other objects, features and advantages of the present invention will become more apparent from the following detailed description when read in conjunction with the accompanying drawings, in which:

FIG. 1 is a diagram of a conventional rubidium atom oscillator;

FIG. 2A is a side view of a rubidium atom oscillator according to an embodiment of the present invention;

FIG. 2B is a plan view of the rubidium atom oscillator shown in FIG. 2A;

FIG. 3A is a perspective view of a hollow cylindrical type high-dielectric-constant material member with a U-shaped cutout portion;

FIG. 3B is a plan view of the hollow cylindrical type high-dielectric-constant material member shown in FIG. 3B;

FIG. 3C is a side view of the material member shown in FIGS. 3A and 3B;

FIGS. 4A, 4B and 4C are respectively views of a resonance mode of TE111 in the hollow cylindrical type cavity resonator;

FIG. 5 is a view of a relationship between the magnetic field distribution in the cavity resonator and an excitation antenna provided therein;

FIGS. 6A, 6B and 6C are views of a change of the resonance frequency as a function of the position of a cutout portion formed in a high-dielectric-material member;

FIG. 7A is a perspective view of a hollow cylindrical high-dielectric-constant material member having a hole formed in its side surface;

FIG. 7B is a plan view of the member shown in FIG. 7A;

FIG. 7C is a side view of the member shown in FIG. 7A; and

FIG. 8 is an exploded perspective view of a light-microwave resonator according to an embodiment of the present invention.

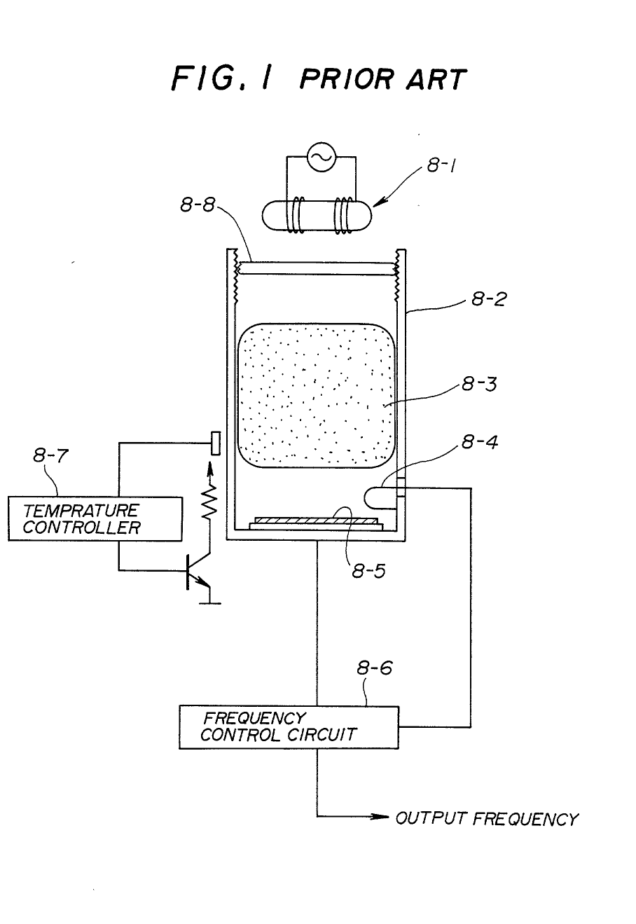

### DESCRIPTION OF THE PREFERRED EMBODIMENTS

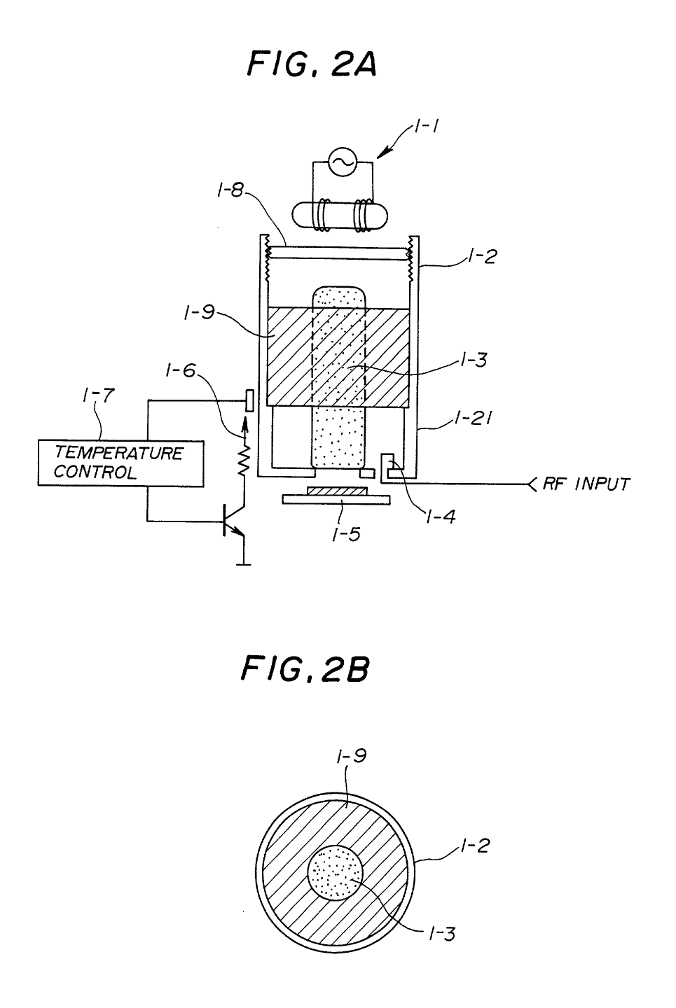

FIG. 2A is a side view of a rubidium atom oscillator according to an embodiment of the present invention, and FIG. 2B is a top view thereof.

Referring to these figures, the rubidium atom oscillator includes a pumping light source 1-1, a hollow cylindrical type cavity resonator (light-microwave resonator) 1-2, a gas cell 1-3, an antenna 1-4, a photodetector 1-5, a heater wire 1-6, a temperature control circuit 1-7, a frequency adjustment diaphragm 1-8, and a hollow cylindrical high-dielectric-constant material member 1-9.

A pumping light emitted by the pumping source 1-1 is incident to the cavity resonator 1-2 through an aperture of the resonator 1-2. A gas is enclosed in the gas cell 1-3, which is provided in the cavity resonator 1-2. An RF input is applied to the antenna 1-4, which excites a microwave in the cavity resonator 1-2. The photodetector 1-5 detects the amount of light from the pumping source 1-1 that has passed through the gas cell 1-3. The heater wire 1-6 heats the cavity resonance 1-2. The temperature control circuit 1-7 controls a supply of electricity to the heater wire 1-6 to control the resonance frequency of the cavity resonator 1-2. The diaphragm 1-8 has screw holes for adjusting the length of the cavity resonator 1-2 for frequency adjustment.

The dielectric material member 1-9 that is shaped in a hollow cylinder is loaded to the cavity resonator 1-2, a wavelength shortening effect will occur if the dielectric material member 1-9 has a higher dielectric constant than that of air. In the wavelength shortening effect, the wavelength of the electromagnetic wave passing through the dielectric material becomes equal to 1/√εr times the wavelength in vacuum where εr denotes the relative dielectric constant of the dielectric material. The wavelength shortening effect results in shortening the wavelength of the microwave that stands in the cavity resonator 1-2. This makes it possible to downsize the cavity resonator 1-2.

It is required that the high-dielectric-constant material member 1-9 has a high dielectric constant appropriate for the wavelength resonance wavelength at which a sufficient light absorption characteristic is available in the gas cell 1-3. Heat should be externally applied to the cavity resonator 1-2 in order to maintain the gas cell 1-3 at a temperature of 70° C. to 75° C. in which the optimal light absorption characteristic is available. The high-dielectric-constant material member 1-9 is required to a high thermal conductivity with respect to the gas cell 1-3. The high-dielectric-constant material member 1-9 that satisfies the above requirements may, for example, be alumina (Al₂O₃) which has a dielectric constant εr of about 10 and is less expensive.

The use of the high-dielectric-constant material member 1-9 results in downsizing of the cavity resonator 1-2 regardless of the position thereof in the cavity resonator 1-2. Preferably, the high-dielectric-constant material member 1-9 is arranged in the central portion of the hollow cylindrical resonator 1-2 along its length direction -when the resonance mode is the TE111 mode. The largest electric field can be obtained in the above central portion. The above arrangement would downsize the cavity resonator 1-2 most effectively.

With the above consideration in mind, according to the embodiment of the present invention, the hollow cylindrical high-dielectric-constant material member 1-9 is arranged in the central portion of the cavity resonator 1-2 along its length direction. The outer wall of the material member 1-9 is brought into contact with the inner wall of the cavity resonator 1-2. The gas cell 1-3 is inserted into a through hole formed in the material member 1-9 extending along the optical axis of the through hole.

The gas cell 1-3 is fixed to and held by the inner wall of the material member 1-9 by means of an adhesive agent or the like. The outer wall of the material member 1-9 is fixed to the inner wall of the cavity resonator 1-2 by means of an adhesive agent or the like. The above-mentioned fixing way makes it possible to fix the gas cell 1-3 and the material member 1-9 to the cavity resonator 1-2 by a simple structure. Further, an additional effect would be expected in which the pumping light introduced into the gas cell 1-3 is enclosed therein.

The light absorbing characteristic in the gas cell 1-3 would be affected by temperature. Thus, the ambient temperature of the cavity resonator 1-2 is measured by a thermistor or the like. The temperature control circuit 1-7 controls a supply of electricity to the heater wire 1-6 wound around the cavity resonator 1-2 so that the temperature of the cavity resonator 1-2 is regulated at a given constant temperature. When the material member 1-9 is made of alumina having a high thermal conductivity, heat can conduct from the cavity resonator 1-2 to the gas cell 1-3 more efficiently. Thus, the gas cell 1-3 can quickly be regulated at the optimal temperature by the temperature control circuit 1-7. This would result in reduction in consumption power for heating and the time necessary for heating, so that the light-microwave resonator having improved responsibility can be configured.

A step or protrusion that protrudes from an inner wall 1-21 of the lower portion of the cavity resonator 1-2 towards the center thereof may be formed in order to mount the material member 1-9 on the step or protrusion. This facilitates the positioning of the material member 1-9 at the time of fixing it to the cavity resonator 1-2.

The high-dielectric-constant material member 1-9 that is loaded as shown in FIGS. 2A and 2B will influence the diameter and length of the cavity resonator 1-2. More particularly, the diameter and length of the cavity resonator 1-2 will both be reduced. By way of practical example, a sample of the cavity resonance 1-2 was produced that has the following specification. The gas cell 1-3 made of glass has a diameter of 10 mm and a length of 20 mm. The glass wall of the gas cell 1-3 is 1 mm thick. The hollow cylindrical cavity high-dielectric-constant material member 1-2 is 13 mm high and a relative dielectric constant of 12. The cavity resonator 1-2 that has the above specification had a volume of 4 cc (the diameter thereof is approximately 16 mm and the length thereof is approximately 25 mm). In contrast, the conventional cavity resonator has a volume of about 30 cc. Thus, the cavity resonator 1-2 is downsized to about ⅛ of the size of the conventional cavity resonator.

As has been described, the cavity resonator can be reduced by properly loading the high-dielectric-constant material thereto. However, the loading of the high-dielectric-constant material would necessarily influence the resonance frequency of the cavity resonator. More strictly, the resonance frequency will greatly be influenced by a dimensional error and an error of the dielectric constant. This results in differences among the individual cavity resonators.

It would be necessary to more precisely produce and shape high-dielectric-constant material member 1-9 in order to reduce the differences in the resonance frequency. However, an improvement in the precision of producing and shaping the material would directly raise the cost of the material member 1-9. The differences in the resonance frequency among the individual cavity resonators may be compensated for by increasing the movable range of the diaphragm 1-8 and thus frequency adjustment range of the cavity resonator 1-2. However, this would prevent downsizing of the cavity resonator.

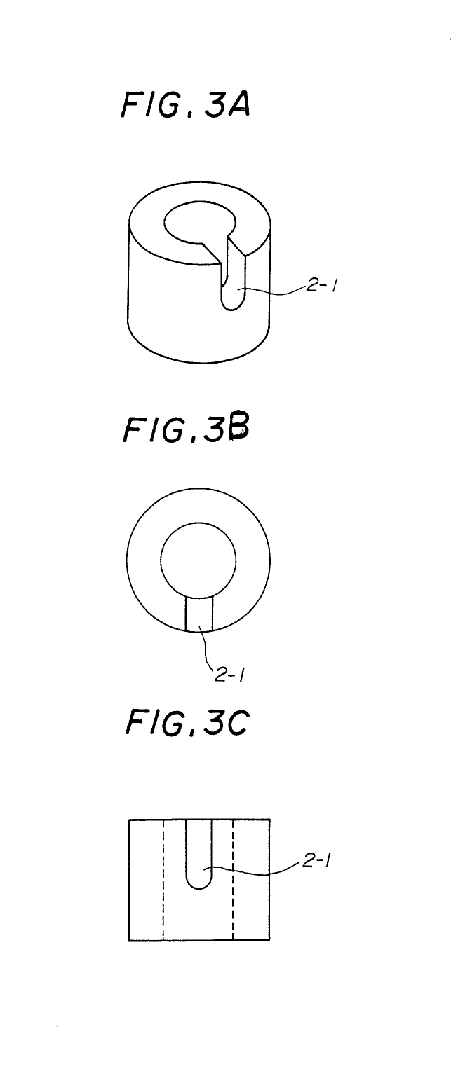

Taking the above into account, the hollow cylindrical high-dielectric-constant material member 1-9 can be modified as shown in FIGS. 3A through 3C. A cutout portion 2-1 may be formed in the wall of the material member 1-9. The cutout portion 2-1, that is a simple structure, makes it possible to adjust the resonance frequency without affecting downsizing of the cavity resonance. The cutout portion 2-1 has a substantially U-shaped structure. Another shape of cutout portion 2-1 may be employed. The cutout portion 1-9 may be formed in an upper or lower end portion alone or both.

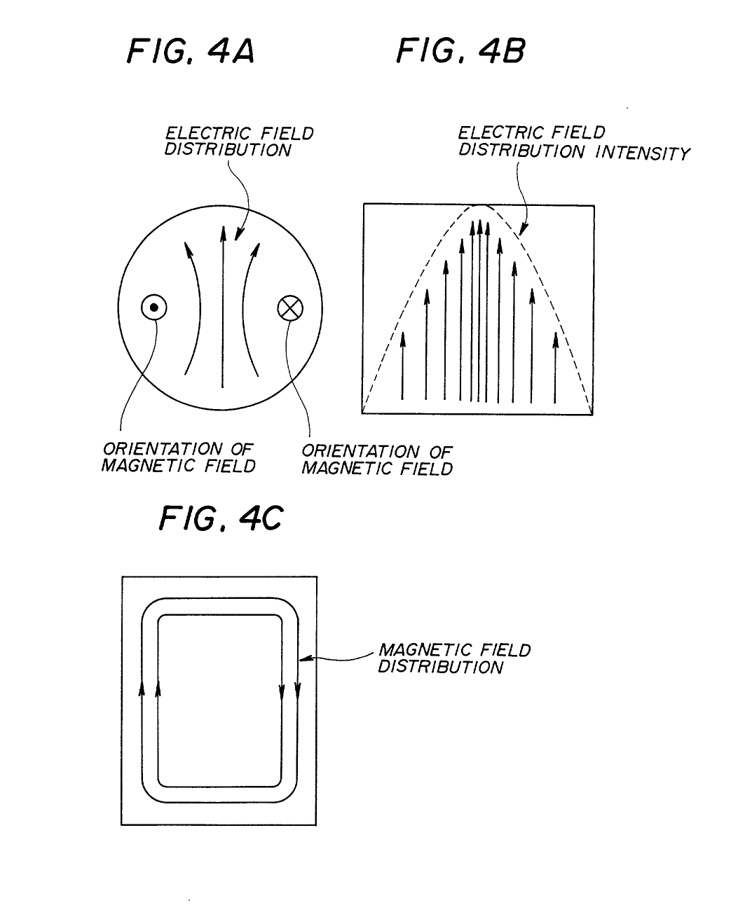

As is well known, the resonance mode of TE111 in a hollow cylindrical type cavity resonator is a mode having an electromagnetic field distribution shown in FIGS. 4A through 4C. FIG. 4A shows an electromagnetic field distribution in a cross section of the cavity resonator in the direction perpendicular to the length direction thereof. FIG. 4B shows an electric field distribution in a cross section of the cavity resonator in the direction parallel to the length direction thereof. FIG. 4C shows a magnetic field distribution in a cross section of the cavity resonator in the direction parallel to the length direction thereof.

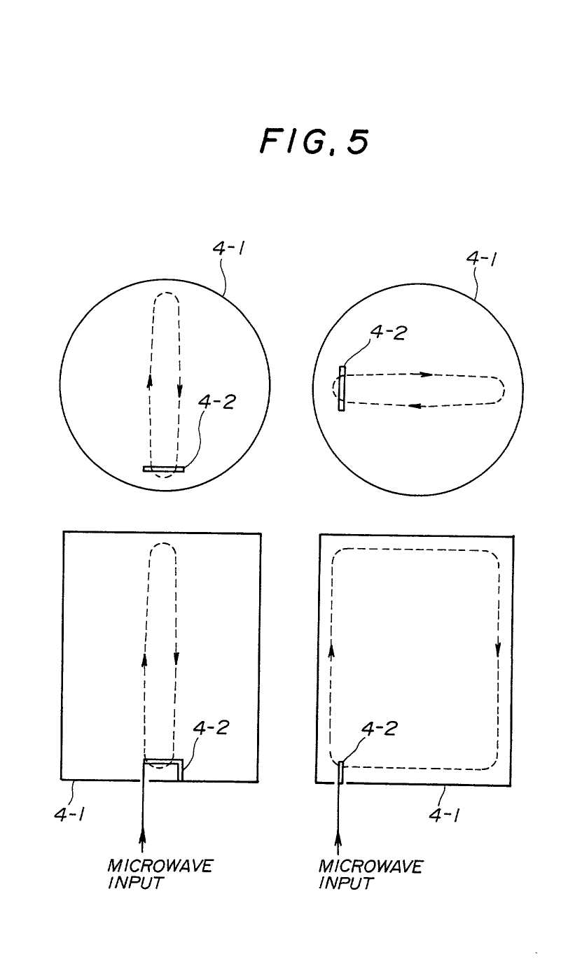

The orientations of the electric and magnetic fields in the cavity resonator 4-1 exclusively depend on the orientation of the antenna 4-1 provided in the cavity resonator 4-1, as shown in FIG. 5. As shown in FIG. 5, the magnetic field is excited in a direction orthogonal to a loop plane formed by an antenna 4-2. The electric field is excited in a direction orthogonal to the magnetic field.

When a hollow cylindrical type high-dielectric-constant material member having no cutout portion is used, the influence of the resonated microwave on the electromagnetic field distribution does not depend on the orientation of the antenna 42 for excitation. In this case, the uniform distribution of the electromagnetic field of the resonated microwave is formed and a given constant resonance frequency can be obtained.

In contrast, another hollow cylindrical type high-dielectric-constant material member with a cutout portion, the dielectric constant will be reduced at the cutout portion. The degree of coupling between the electromagnetic field and the dielectric material would be varied due to the relative positional relationship between the antenna 402 and the cutout portion. Hence, the resonance frequency obtained in the position in which the highest degree of coupling is obtained differs from that obtained in the position in which the lowest degree of coupling is obtained.

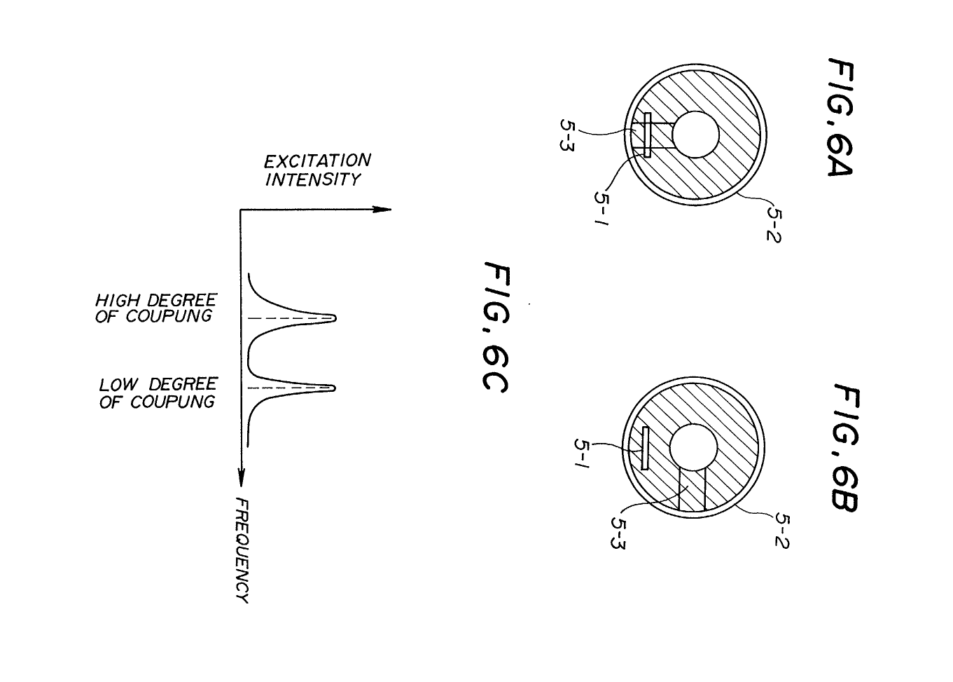

FIGS. 6A through 6C show a change of the resonance frequency that depends on the relative positional relationship between an antenna 5-1 and a cutout portion 5-3 of a high-dielectric-constant material member 5-2. More particularly, FIG. 6A shows a relative position in which the highest degree of coupling between the electromagnetic field distribution and the dielectric material is obtained. FIG. 6B shows a relative position in which the lowest degree of coupling between the electromagnetic field distribution and the dielectric material is obtained. FIG. 6C shows a resonance point at which the degree of coupling is the highest, and another resonance point at which the degree of coupling is the lowest.

As shown in FIG. 6C, the different resonance points appear in the positions in which the highest and lowest degrees of coupling are observed. The wavelength in the position in which the degree of coupling is high is shortened due to the wavelength shortening effect. This reduces the resonance frequency of the cavity resonator. In contrast, a comparatively high resonance frequency of the cavity resonator is obtained in the position in which the degree of coupling is low.

The above function is positively utilized to change the arrangement of the cutout portion, thereby making it possible to easily adjust the resonance frequency. In an experiment, a resonance frequency change of about 80 MHz was observed when the U-shaped cutout portion is changed. The high-dielectric-constant material member used in the experiment had an outer diameter of 16 mm, an inner diameter of 10 mm and a height of 13 mm, and had a relative dielectric constant of 12. The U-shaped cutout portion formed in the above member had a radius of 2 mm, and a depth of 4.5 mm.

The above corresponds to a change of the resonance frequency obtained by moving, by 4 mm, a diaphragm of a cavity resonator that has a diameter of 16 mm and a length of 25 mm. Thus, it is possible to adjust the resonance frequency over 160 MHz by changing the arrangement (position) of the cutout portion and changing the position of the diaphragm by 4 mm. The above frequency adjustment range is sufficient to compensate for the differences among the individual high-dielectric-constant material members introduced during the production process.

The cutout portion is not limited to the U shape, but may have an arbitrary shape such as V shape, rectangular shape, trapezoidal shape or semi-circle shape. A plurality of cutout portions may be used.

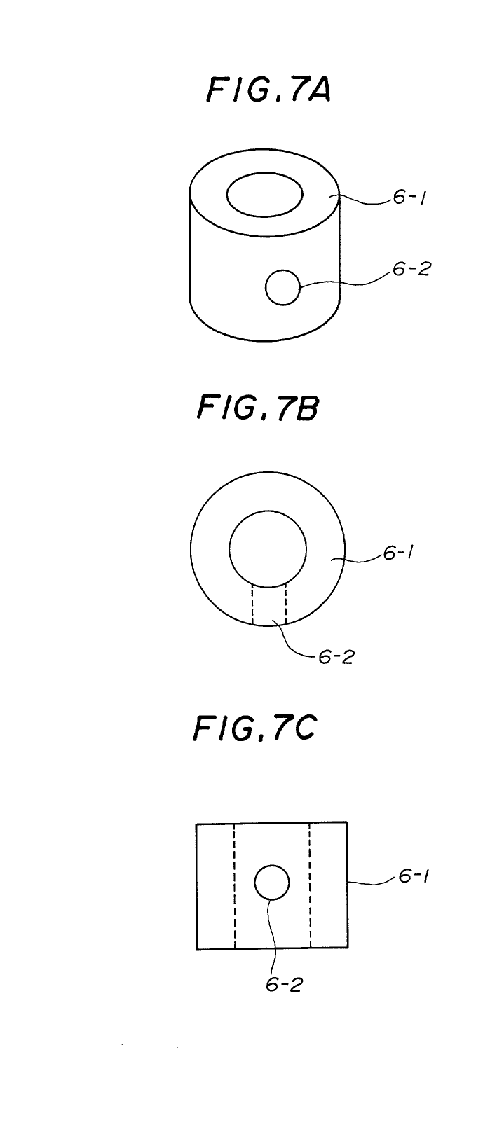

As shown in FIGS. 7A through 7C, a hole or a recess portion 6-2 having an arbitrary shape may be formed in a side surface of a hollow cylindrical shape high-dielectric-constant material 6-1 in an arbitrary manner. Such a hole or a recess portion 6-2 will function in the same manner as the U-shaped cutout portion. More specifically, the degree of coupling between the electromagnetic field distribution and the dielectric material depends on the relative positional relationship between the hole or recess portion and the antenna. Thus, the resonance frequency can be adjusted by changing the position of the hole or recess portion.

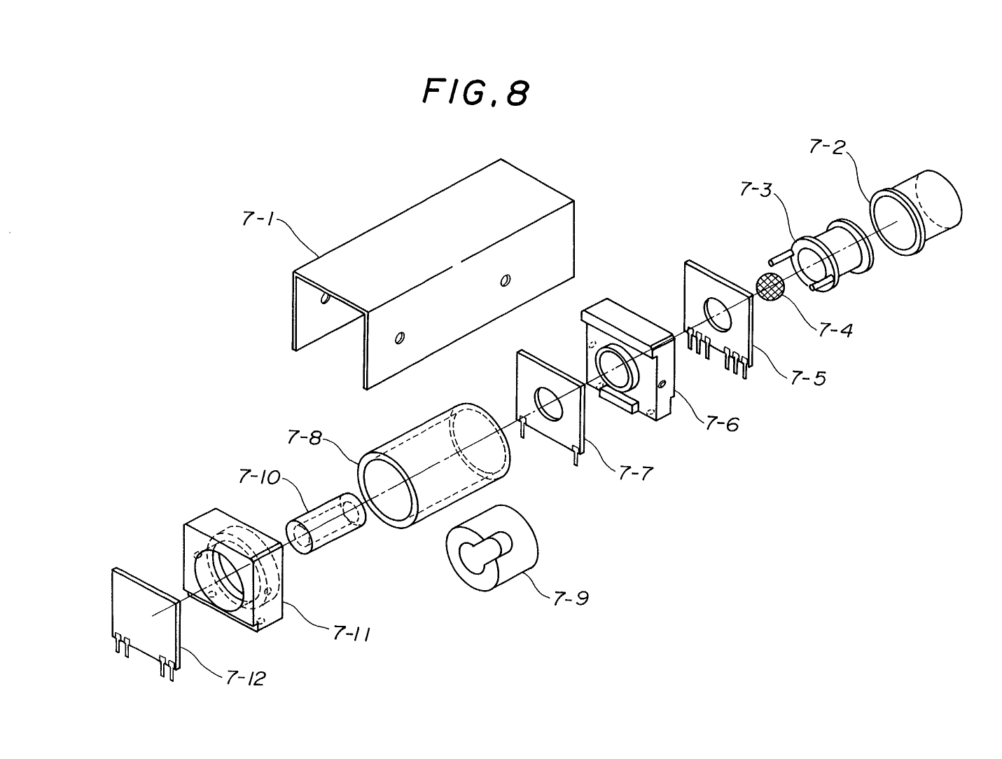

FIG. 8 is an exploded perspective view of a light-microwave resonator according to an embodiment of the present invention. The light-microwave resonator shown in FIG. 8 has a shield cover 7-1 in which housed are a cap 7-2 for a pumping source, a rubidium lamp excitation coil 7-3, a rubidium lamp 7-4, a lamp printed-circuit board 7-5, a first molded block 7-6, an excitation antenna printed-circuit board 7-6, a cavity resonator 7-8, a high-dielectric-constant material member 7-9, a rubidium gas cell 7-10, a second molded block 7-11, and a preamplifier printed-circuit board 7-12.

The high-dielectric-constant material member 7-9 is inserted into the cavity resonator 7-8. The rubidium gas cell 7-10 is inserted into the high-dielectric-constant material member 7-9. A diaphragm for frequency adjustment and a photodetector are attached to the second molded block 7-11. An amplifier circuit that amplifies the output signal of the photodetector is mounted on the preamplifier printed-circuit board 7-12. Further, a heater wire (not shown) for heating the cavity resonator 7-8 and a coil (not shown) for applying the static magnetic field are wound around the cavity resonator 7-8.

An orthohexahedron cavity resonator having high thermal conductivity may be substituted for the hollow cylindrical cavity resonator. In this case, high-dielectric-constant material is shaped so that the outer walls of the shaped member closely contacts the inner walls of the orthohexahedron cavity resonator. The use of the orthohexahedron cavity resonator results in advantages similar to those of the hollow cylindrical type cavity resonators.

The shape of the high-dielectric-constant material member having high thermal conductivity may be modified in such a way as to match the shape of the cavity resonator and that of the gas cell. The high-dielectric-constant material member is not limited to a cylindrical shape, but may be formed by a combination of a plurality of members.

The present invention is not limited to the specifically disclosed embodiments, and variations and modifications may be made without departing from the scope of the present invention.

The present application is based on Japanese Priority Application No. 2000-126946, the entire contents of which are hereby incorporated by reference.

What is claimed is:

1. A rubidium atom oscillator of a gas cell resonator type comprising:
a cavity resonator having a gas cell in which rubidium gas is enclosed; and
a dielectric material member that has thermal conductivity and closely contacts an inner wall of the cavity resonator parallel to an optical axis of an incident light emitted from a pumping source,
the gas cell being inserted into the dielectric material member having the thermal conductivity along the optical axis.

2. The rubidium atom oscillator as claimed in claim 1, wherein:
the dielectric material member has a hollow cylindrical shape having an outer wall that contacts the inner wall of the cavity resonator; and
the gas cell is inserted into an inner wall of the dielectric material member so as to be held by the dielectric material member.

3. The rubidium atom oscillator as claimed in claim 1, wherein the dielectric material member has a hollow cylindrical shape; and
the cavity resonator has a hollow cylindrical shape.

4. The rubidium atom oscillator as claimed in claim 1, wherein the dielectric material member has at least one cutout portion; and
a resonance frequency of the cavity resonator depends on a relative positional relationship between the cutout portion and an electromagnetic field distribution that stands in the cavity resonator.

5. The rubidium atom oscillator as claimed in claim 4, wherein said at least cutout portion is formed in an upper or lower end of the dielectric material member or both.

6. The rubidium atom oscillator as claimed in claim 1, wherein the dielectric material member has at least one hole; and
a resonance frequency of the cavity resonator depends on a relative positional relationship between the hole and an electromagnetic field distribution that stands in the cavity resonator.

7. The rubidium atom oscillator as claimed in claim 1, wherein said at least one hole is formed in a side surface of the dielectric material member.

8. The rubidium atom oscillator as claimed in claim 1, wherein the dielectric material member comprises alumina.

9. A light-microwave resonator comprising:
a shield cover; and
a rubidium atom oscillator of a gas cell resonator type housed in the shield cover, said rubidium atom oscillator comprising:
a cavity resonator having a gas cell in which rubidium gas is enclosed; and
a dielectric material member that has thermal conductivity and closely contacts an inner wall of the cavity resonator parallel to an optical axis of an incident light emitted from a pumping source,
the gas cell being inserted into the dielectric material member having the thermal conductivity along the optical axis.
